(19) United States
(12) Patent Application Publication
(10) Pub. No.: US 2012/0032194 A1
(43) Pub. Date: Feb. 9, 2012

(54) LIGHTING MODULE WITH HIGH COLOR RENDING PROPERTY

(75) Inventors: Chih-Hung WEI, Tu Cheng City (TW); Ming-Chang Wu, Tu Cheng City (TW); Chih-Yang Hsu, Tu Cheng City (TW); Ding-Yuan Jheng, Tu Cheng City (TW); Ming-Yu Hsu, Tu Cheng City (TW)

(73) Assignee: High Power Lighting Corp.

(21) Appl. No.: 12/853,219

(22) Filed: Aug. 9, 2010

(51) Int. Cl. H01L 33/50

(52) U.S. Cl. 257/88; 257/E33.067

(57) ABSTRACT

A lighting module with high rending property includes a substrate, a plurality of first light emitting diode (LED) chips, a plurality of second LED chips and a wavelength conversion layer. The first LED chips are deposed on the substrate and electrically connected to the substrate. The second LED chips are deposed on the substrate and electrically connected to the substrate. The wavelength conversion layer seals the first LED chips and the second LED chips. The light emitted from the LED chips and the light emitted from the wavelength conversion layer caused by an excitation by the LED chips are mixing to form warm white light with high color rending property. The number ratio of the first LED chips to the second LED chips deposed on the substrate is 2:1.

### BACKGROUND OF THE INVENTION

1. Field of the Invention

The present invention is related to a lighting module, and more particular to a lighting module which used light emitting diodes as a light source having a feature of high color rending index.

2. Description of Prior Art

Light emitting diode (LED) is kind of semiconductor device, which exploits the property of direct-bandgap semiconductor material to convert electric energy into light energy efficiently and has advantages of long lifetime, high stability and low power consumption. LED is primarily used for the applications of indication lamp, traffic sign and sign broad in its early history, and extend to lighting field when white light LED is successfully developed.

The traditional white LED is composed of blue LED chip and yellow phosphor, blue light component occupies major portion of the white light spectrum. The color temperature is high (around 6000K). The red light component in this white light is not sufficient and the color rending property of the white LED is poor. Moreover, in the process of dispensing epoxy, the epoxy tends to overflow to the sidewall of the substrate to influence the uniform of the mixed light.

To solve the problem of poor color rending property of the white LED, red phosphor or green phosphor are added in the packaging process of the white LED, thus reducing color temperature and enhancing color rending property. However, the uniformity of the phosphor is difficult to control and the property of thus-formed white LED is not ideal yet.

Moreover, a red LED is deposed inside a secondary lens with the white LED, thus achieving a white light lighting module through secondary optics. In the actual application, the white light lighting module emits not only warm light but also red light which human eye can easily observe.

Furthermore, the secondary lens will fall off due to an external force; hence, the secondary lens can not protect the LED chip. When the white light lighting module is used for a long time, the heat produced by the LED brings about thermal expansion, this will bring the secondary lens fall off to reduce the luminance intensity of the lighting module.

### SUMMARY OF THE INVENTION

Accordingly, the present invention is direct to a lighting module with high color rendering property and the lighting module can emit warm white light.

Therefore, the present invention provides a light module with high color rending property. The lighting module comprises a substrate, a plurality of first light emitting diode chips, a plurality of second light emitting diode chips and a wavelength conversion layer. The first light emitting diode chips are deposed on the substrate and electrically connected to the substrate. The second light emitting diode chips are deposed on the substrate and electrically connected to the substrate and the first light emitting diode chips. The wavelength conversion layer seals the first light emitting diode chips and the second light emitting diode chips.

In more particularly, the first light emitting diode chips and the second light emitting diode chips are arranged in number ratio of 2:1, the light emitted from the first light emitting diode chips and the second light emitting diode chips are mixed with light emitted from the wavelength conversion layer after the wavelength conversion layer is excited by the light emitting diode chips to form warm white light with high color rending property.

The lighting module with high color rending property according to the present invention mixes the light from the light emitting diode chips of different color and the wavelength conversion layer to provide a light source with low color temperature and high color rending property. The lighting module according the present invention has simply manufacture process and lower cost in comparison with conventional light module.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 is a top view of the lighting module with high color rending property according to the present invention;

FIG. 2 is a sectional view of the lighting module with high color rending property according to the present invention;

FIG. 3 is a partially enlarged view for the trench structure shown in FIG. 2; and

FIG. 4 shows another top view of the lighting module with high color rending property according to the present invention.

### DETAILED DESCRIPTION OF THE INVENTION

The present invention is described below in detail with reference to accompanying drawings. It should be noted that like elements are denoted by the same reference numerals throughout the disclosure.

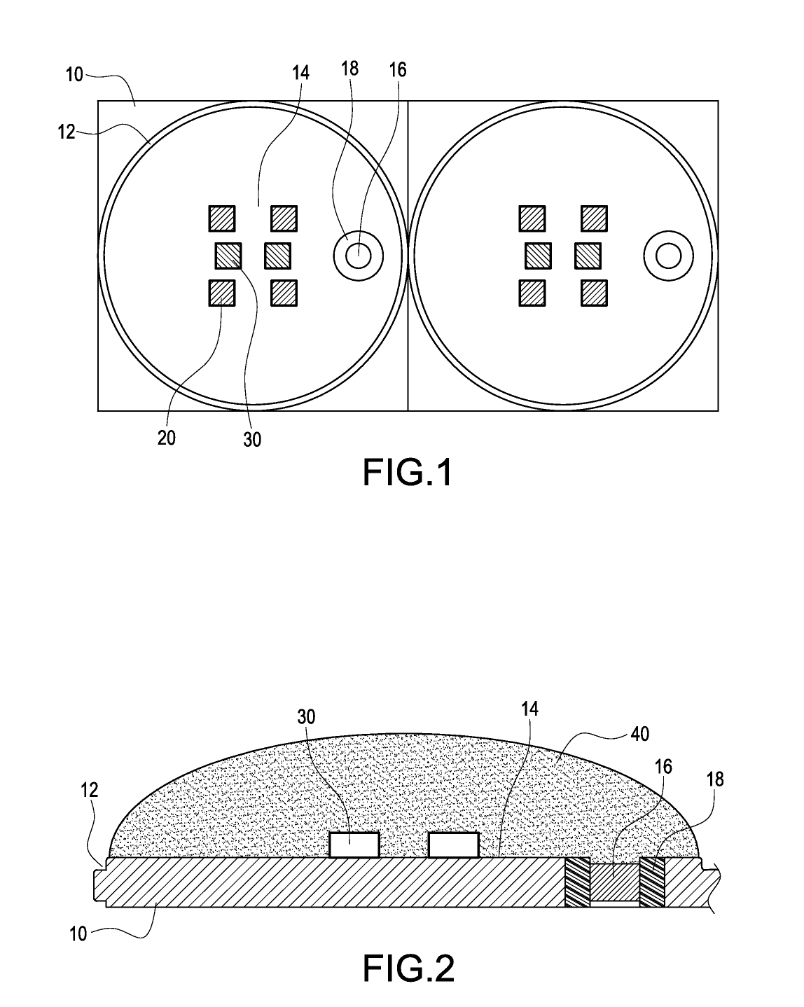

FIG. 1 and FIG. 2 show the top view and sectional view of the lighting module with high color rending property according to the present invention, respectively. The lighting module comprises a substrate 10, a plurality of first light emitting diode chips 20, a plurality of second light emitting diode chips 30, and a wavelength conversion layer 40.

The substrate 10 further comprises a trench structure 12. The trench structure 12 is deposed to enclose an island 14. In this embodiment, the trench structure 12 is circularly deposed on the substrate 10. The trench structure 12 is provided by etching, plating or machining process. The thickness of the substrate 10 is between 0.1 millimeter and 0.5 millimeter, and the depth of the trench structure 12 is between 0.03 millimeter and 0.1 millimeter.

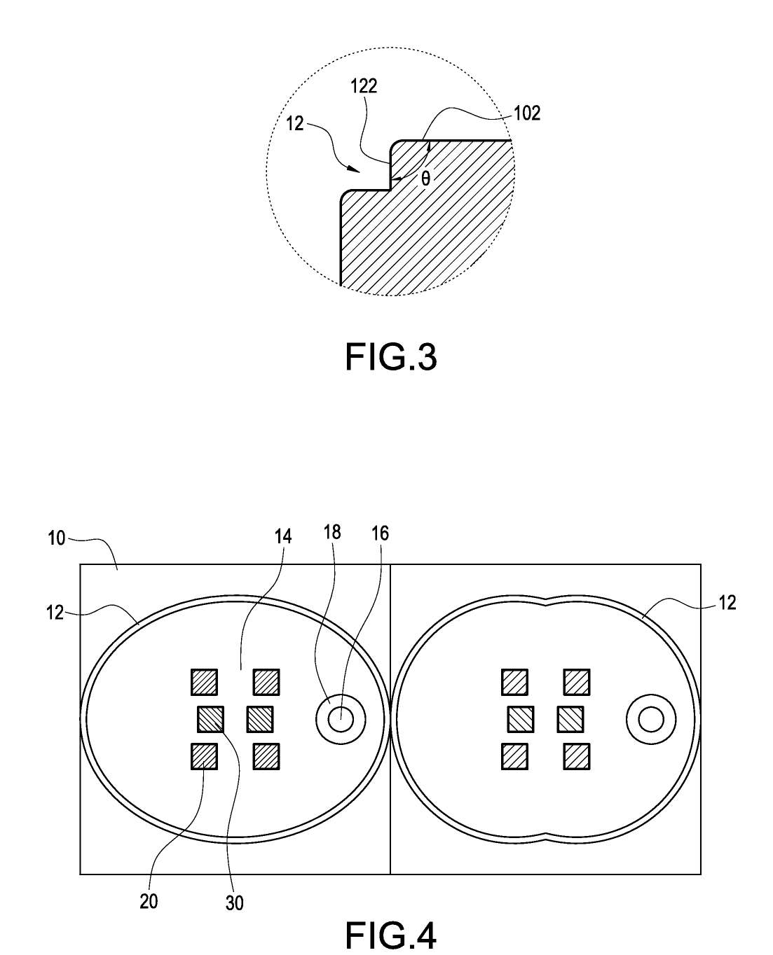

FIG. 3 is a partially enlarged view for the trench structure shown in FIG. 2. An interior sidewall 122 of the trench structure 12 and the top surface 102 of the substrate 10 has a lead angle θ, and the lead angle θ is approximately 90 degree.

Referring to FIG. 1 and FIG. 2, an electrical connector 16 is through the substrate 10 and deposed on the island 14. The electrical connector 16 is package by an isolated layer 18 such that the electrical connector 16 is electrically isolated with the substrate 10.

The first light emitting diode chips 20 are deposed on the island 14, and electrically connected to the substrate 10 (not shown). More particularly, the spectral emission of each first light emitting diode chip 20 lies in the wavelength range from 455 nm to 465 nm, which is corresponding to the wavelength of blue light.

The second light emitting diode chips 30 are deposed on the island 14. The second light emitting diode chips 20 are electrically connected to the substrate 10 and the first light emitting diode 20 (not shown). The spectral emission of each second light emitted chip 30 lies in the wavelength range from 620 nm to 625 nm, which is corresponding to the wavelength of red light.

The number ratio of the first light emitting diode chips 20 with respect to the second light emitting diode chips 30 is 2:1. Hence, the lighting module can provide a better color rending property, where the color rendering index is at least 90.

Moreover, the first light emitting diode chips 20 and the second light emitting diode chips 30 are axial-symmetrically deposed on the substrate 10. The second light emitting diode chips 30 are centralized on the center of the island 14. The first light emitting diode chips 20 surround the second light emitting diode chips 30. More particularly, the arrangement between each second light emitting diode chips 30 is more concentrative than the arrangement between each first light emitting diode chips 20. The arrangement capable of well mixing the light emits by the first light emitting chips 20 and the second light emitting diode chips 30, and enhancing the uniformity of light the lighting module emits.

The wavelength conversion layer 40 comprises photoluminescence phosphor, which converts blue light emitted from the first light emitting diode chips 20 into light having a longer wavelength. The wavelength conversion layer 40 is dotted on the substrate 10 such that the wavelength conversion layer 40 covers the first light emitting diode chips 20 and the second light emitting diode chips 30. The wavelength conversion layer 40 forms a spherical convex emitting surface. The range covered by the wavelength conversion layer 40 is smaller than that of the trench structure 12. Moreover, the wavelength conversion layer 40 covers the island 14. A surface tension force of the wavelength conversion layer 40 can prevent the wavelength conversion layer 40 from flowing out of the island 14 and from flowing to the trench structure 12. Therefore, the wavelength conversion layer 40 can be retained on the surface of the island 14 and cover the light emitting diode chips 20 and 30. The problem of non-uniform light caused by incomplete covering the light emitting diode chips 20 and 30 can be prevented for the wavelength conversion layer 40. The wavelength conversion layer 40 can be transparent surface or translucent surface.

Moreover, since the limitation of the wavelength conversion layer 40 by the island 14, the wavelength conversion layer 40 can completely cover the first light emitting diode 20 and the second light emitting diode 30. The light emits by the light emitting diode chips 20, 30 all go through the wavelength conversion layer 40, whereby the problem of non-uniformity in light emitted from the light emitting diode emits. The diffusion angle of the spherical convex emitting surface which the light goes through are 160 to 170 degrees, thus greatly enhancing light extraction efficiency.

In the actual lighting, a white light is generated by mixed the blue light and the light which the wavelength conversion layer 40 emits as being excited by the first light emitting diode chips 20. The second light emitting diode chips 30 can not excites the wavelength conversion layer 40, but the red light emitted by the second light emitting diode chips 30 mixing the white light to generate a white light with lower color temperature.

The surface of the island 14 can be treated by sand-blasting process to form an uneven surface to increase the adhesive force of the wavelength conversion layer 40. Moreover the island 14 further comprises characters or a symbol produced by etching, plating or machining process.

Moreover, reference is made to FIG. 4, which is a top view of the lighting module with high color rending property according to the present invention. The trench structure 12 is of elliptic or double-ring shaped by erosion, etching or machining to prevent the wavelength conversion layer 40 overflow therein in package process.

To sum up, the lighting module with high color rending property according to the present invention mixes the light from the light emitting diode chips of different color and the wavelength conversion layer to provide a light source with low color temperature and high color rending property. The lighting device with high color rending property according to the present invention has simple manufacture process and lower cost in comparison with lighting module with phosphor of different colors or the lighting module modifying light with second optical lens. The trench structure deposed on the substrate can effectively solve the problem the overflow of the wavelength conversion layer.

Although the present invention has been described with reference to the foregoing preferred embodiments, it will be understood that the invention is not limited to the detail thereof. Various equivalent variations and modifications can still occur to those skilled in this art in view of the teachings of the present inventions. Thus, all such variations and equivalent modifications are also embraced within the scope of the invention as define in the appended claims.

What is claimed is:

1. A lighting module with high color rending property, comprising:
a substrate,
a plurality of first light emitting diode chips, deposed on the substrate and electrically connected to the substrate;
a plurality of second light emitting diode chips, deposed on the substrate and electrically connected to the substrate; and
a wavelength conversion layer, sealing the first light emitting diode chips and the second light emitting diode chips;
wherein the first light emitting diode chips and the second light emitting diode chips are arranged in number ratio of 2:1, the light emitted from the first light emitting diode chips and the second light emitting diode chips are mixed with light emitted from the wavelength conversion layer after the wavelength conversion layer is excited by the light emitting diode chips to form warm white light with high color rending property.

2. The lighting module with high color rending property of claim 1, further comprises a trench structure, deposed on the substrate, wherein an interior sidewall of the trench structure has a lead angle with respect to a top surface of the substrate.

3. The lighting module with high color rending property of claim 2, the range of the wavelength conversion layer is small than that of the trench structure.

4. The lighting module with high color rending property of claim 1, wherein the first light emitting diode chips and the second light emitting diode chips are axial-symmetrically deposed on the substrate.

5. The lighting module with high color rending property of claim 4, wherein the first light emitting diode chips are deposed around the second light emitting diode chips.

6. The lighting module with high color rending property of claim 1, wherein the wavelength conversion layer seals the first light emitting diode chips and the second light emitting diode chips and formed a spherical convex emitting surface.

7. The lighting module with high color rending property in claim 6, wherein the diffusion angle of the spherical convex emitting surface are 160 to 170 degrees.

8. The lighting module with high color rending property in claim 1, wherein the color rendering index of the lighting module is at least 90.

9. The lighting module with high color rending property in claim 1, wherein the wavelength conversion layer comprises photoluminescence phosphor.
